(19) United States
(12) Patent Application Publication
(10) Pub. No.: US 2025/0040182 A1
(43) Pub. Date: Jan. 30, 2025

(54) ASYMMETRIC VERTICAL THIN FILM TRANSISTOR SELECTOR

(71) Applicant: Micron Technology, Inc., Boise, ID (US)

(72) Inventors: Paolo Fantini, Vimercate (IT); Andrea Ghetti, Concorezzo (IT); Benjamin Chu-Kung, Boise, ID (US); Sara Moon Villa, Brugherio (IT)

(21) Appl. No.: 18/781,766

(22) Filed: Jul. 23, 2024

Related U.S. Application Data
(60) Provisional application No. 63/528,845, filed on Jul. 25, 2023.

(51) Int. Cl. H01L 29/786; G11C 16/04; H01L 29/417; H01L 29/66; H10B 41/27

(52) U.S. Cl. CPC H01L 29/78642; G11C 16/0483; H01L 29/41733; H01L 29/6675; H01L 29/78696; H10B 41/27

(57) ABSTRACT

Systems, methods, and apparatuses are provided for an asymmetric vertical thin film transistor selector. An apparatus includes first and second source/drain regions formed on a substrate, a channel separating the first source/drain region and the second source/drain region, and a gate separated from the channel by a gate dielectric material. The first source/drain region, the second source/drain region, the channel, and the gate form a vertical thin film transistor, a first end of the channel is coupled to the first source/drain region and extends beyond a first end of the gate, and a second end of the channel is coupled to the second source/drain region and does not extend beyond a second end of the gate that is opposite the first end of the gate. A contact in the substrate is coupled to the first source/drain region and a sense line is coupled to the second source/drain region.

### PRIORITY INFORMATION

This application claims the benefit of U.S. Provisional Application No. 63/528,845, filed on Jul. 25, 2023, the contents of which are incorporated herein by reference.

### TECHNICAL FIELD

The present disclosure relates generally to memory devices, and more particularly, to an asymmetric vertical thin film transistor selector.

### BACKGROUND

Memory devices are typically provided as internal, semiconductor, integrated circuits and/or external removable devices in computers or other electronic devices. There are many different types of memory including volatile and non-volatile memory. Volatile memory can require power to maintain its data and can include random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), and resistance variable memory such as phase change random access memory (PCRAM), resistive random access memory (RRAM), ferroelectric random access memory (FERAM), magnetic random access memory (MRAM), and programmable conductive memory, among others.

Memory devices can be utilized as volatile and non-volatile memory for a wide range of electronic applications in need of high memory densities, high reliability, and low power consumption. Non-volatile memory may be used in, for example, personal computers, portable memory sticks, solid state drives (SSDs), digital cameras, cellular telephones, portable music players such as MP3 players, and movie players, among other electronic devices.

Memory devices can include memory cells that can store data based on the charge level of a storage element or can store data based on their conductivity state. Such memory cells can be programmed to store data corresponding to a target data state by varying the charge level of the storage element or by varying the conductivity level of the storage element. For example, sources of an electrical field or energy, such as positive or negative electrical pulses (e.g., positive or negative voltage or current pulses), can be applied to the memory cell (e.g., to the storage element of the cell) for a particular duration to program the cell to a target data state.

A memory cell can be programmed to one of a number of data states. For example, a single level memory cell (SLC) can be programmed to a targeted one of two different data states, which can be represented by the binary units 1 or 0 and can depend on whether the capacitor of the cell is charged or uncharged. As an additional example, some memory cells can be programmed to a targeted one of more than two data states (e.g., 1111, 0111, 0011, 1011, 1001, 0001, 0101, 1101, 1100, 0100, 0000, 1000, 1010, 0010, 0110, and 1110). Such cells may be referred to as multi state memory cells, multiunit cells, or multilevel cells (MLCs). MLCs can provide higher density memories without increasing the number of memory cells since each cell can represent more than one digit (e.g., more than one data bit).

### BRIEF DESCRIPTION OF THE DRAWINGS

FIG. 1 is an example computing system that includes a memory sub-system in accordance with a number of embodiments of the present disclosure.

FIG. 2 is an example of a portion of a three-dimensional (3D) vertical memory array in accordance with a number of embodiments of the present disclosure.

FIG. 3 is a schematic view of an asymmetric vertical thin film transistor selector in accordance with a number of embodiments of the present disclosure.

FIGS. 4A-4G are cross-sectional views illustrating an example method for forming asymmetric vertical thin film transistors in accordance with a number of embodiments of the present disclosure.

### DETAILED DESCRIPTION

Embodiments of the present disclosure describe forming an asymmetric vertical thin film transistor (TFT) selector. An embodiment includes an apparatus comprising a first source/drain region and a second source/drain region formed on a substrate, a channel that separates the first source/drain region and the second source/drain region, and a gate separated from the channel by a gate dielectric material. The first source/drain region, the second source/drain region, the channel and the gate form a vertical TFT. Further, the first end of the channel is coupled to the first source/drain region and extends beyond a first end of the gate and a second end of the channel is coupled to the second source/drain region and does not extend beyond a second end of the gate that is opposite the first end of the gate. The apparatus further includes a contact in the substrate coupled to the first source/drain region and a sense line coupled to the second source/drain region.

Vertical TFTs can be incorporated into different types of vertical memory. As used herein, the term “vertical TFT” refers to an access device (e.g., transistor) that is vertically oriented within a memory. A vertical TFT can provide access to components coupled to the vertical TFT such as a sense line coupled to the vertical TFT, an access line coupled to the vertical TFT, and a storage node (e.g., element) coupled to the vertical TFT.

For some memory operations, a vertical TFT may need to have an on current of 100 microamps to be used as an access line selector and an off current of less than 1 nanoamp to be used as a pillar selector. However, a vertical TFT formed through previous approaches cannot sustain both an off current of less than 1 nanoamp and an on current of 100 microamps.

A vertical TFT in accordance with embodiments of the present disclosure, however, can sustain both an off current of less than 1 nanoamp and an on current of 100 microamps. The vertical TFT can sustain those conditions by forming the vertical TFT as an asymmetric vertical TFT. In an asymmetric vertical TFT, one end of the channel of the vertical TFT can extend beyond one end of the gate of the vertical TFT, while the other (e.g., opposite) end of the channel does not extend beyond the opposite end of the gate of the vertical TFT. The asymmetric property of the asymmetric vertical TFT can move the sense line (e.g., digit line) coupled to the vertical TFT further away from the channel than previous approaches. This allows a single vertical TFT to sustain an off current of less than 1 nanoamp and an on current of 100 microamps, thereby allowing the vertical TFT to function as both a pillar selector and an access line selector.

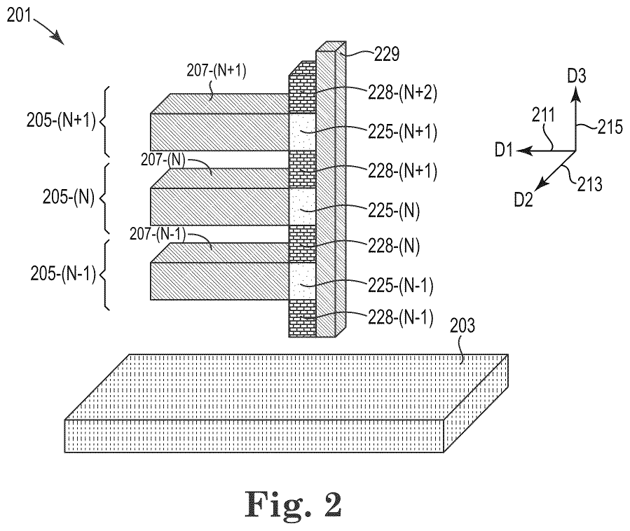

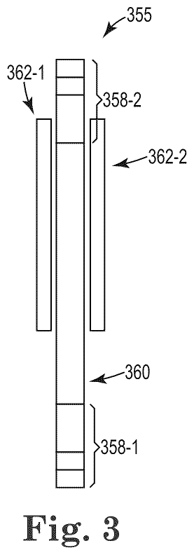

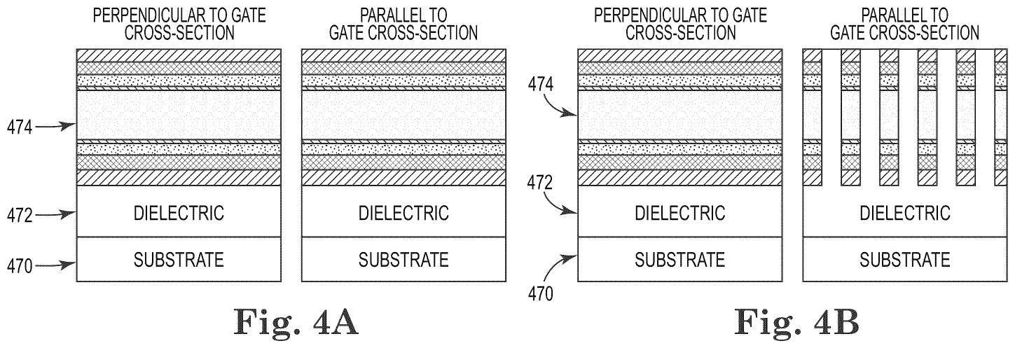

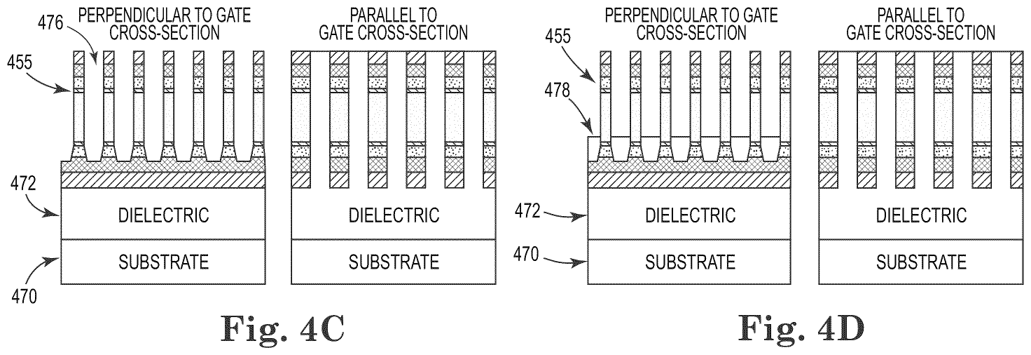

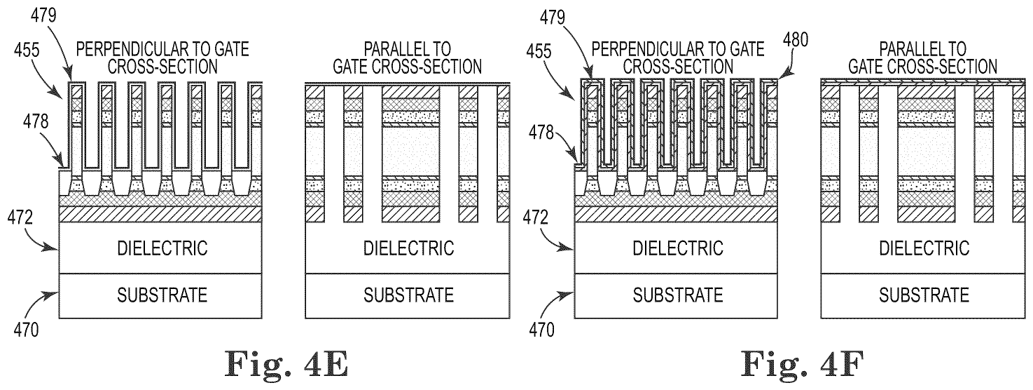

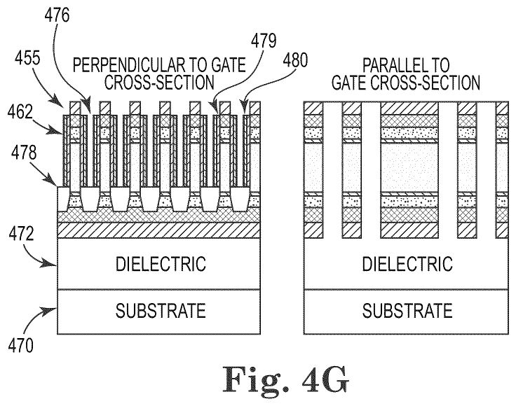

The figures herein follow a numbering convention in which the first digit or digits correspond to the figure number of the drawing and the remaining digits identify an element or component in the drawing. Similar elements or components between different figures may be identified by the use of similar digits. For example, reference numeral 362 may reference element “62” in FIG. 3, and a similar element may be referenced as 462 in FIG. 4. Analogous elements within one figure may be referenced with a reference numeral followed by a hyphen and another numeral or a letter. For example, 362-1 may reference element 362-1 in FIGS. 3 and 362-2 may reference element 362-2, which may be analogous to element 362-1. Such analogous elements may be generally referenced without the hyphen and extra numeral or letter. For example, elements 362-1 and 362-2 may be generally referenced as 362.

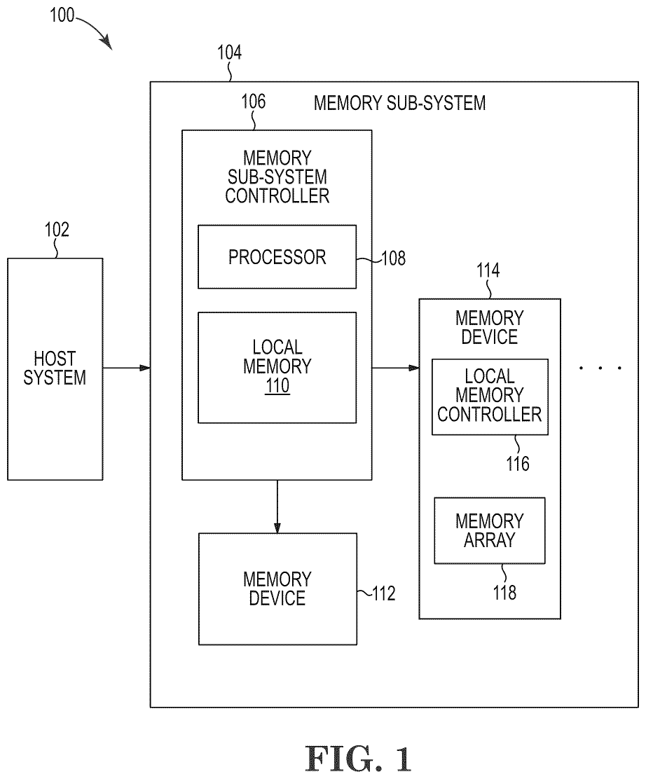

FIG. 1 illustrates an example computing system 100 that includes a memory sub-system 104 in accordance with some embodiments of the present disclosure. The memory sub-system 104 can include media, such as one or more volatile memory devices (e.g., memory device 114), one or more non-volatile memory devices (e.g., memory device 112), or a combination of such.

A memory sub-system 104 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 102 that is coupled to one or more memory sub-systems 104. In some embodiments, the host system 102 can be coupled to different types of memory sub-systems 104. FIG. 1 illustrates one example of a host system 102 coupled to one memory sub-system 104. As used herein, the term “coupled to” or “coupled with” can refer to a connection between components, which can be an indirect communicative connection or direct communicative connection (e.g., without intervening components), whether wired or wireless, including connections such as electrical, optical, magnetic, etc.

The host system 102 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 102 uses the memory sub-system 104, for example, to write data to the memory sub-system 104 and read data from the memory sub-system 104.

The host system 102 can be coupled to the memory sub-system 104 via an interface (e.g., a physical host interface). Examples of an interface can include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), Universal Serial Bus (USB), or any other interface. The interface can be used to transmit data between the host system 102 and the memory sub-system 104. The interface can provide a way for passing control, address, data, and other signals between the memory sub-system 104 and the host system 102. FIG. 1 illustrates a memory sub-system 104 as an example. In general, the host system 102 can access multiple memory sub-systems via a same communication connection, multiple separate communication connections, and/or a combination of communication connections.

The memory devices 112, 114 can include any combination of the different types of volatile memory devices and/or non-volatile memory devices. The volatile memory devices can be, but are not limited to, random access memory (RAM), such as dynamic random access memory (DRAM) and synchronous dynamic random access memory (SDRAM). The non-volatile memory devices can be, but are not limited to, flash memory, ferroelectric memory, and/or vertical chalcogenide-based memory.

Each of the memory devices 112, 114 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 112, 114 can include one or more arrays of memory cells such as SLCs, MLCs, TLCs, QLCs, or any combination of such. In some embodiments, a particular memory device 112, 114 can include an SLC portion, and an MLC portion, a TLC portion, a QLC portion, or a PLC portion of memory cells. The memory cells of the memory devices 112, 114 can be grouped as pages that can refer to a logical unit of the memory device 112, 114 used to store data.

A memory sub-system controller 106 (or controller 106 for simplicity) can communicate with the memory devices 112, 114 to perform operations such as reading data, writing data, or erasing data at the memory devices 112, 114 and other such operations. The memory sub-system controller 106 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 106 can be a microcontroller, special purpose logic circuitry (e.g., a field programmable gate array (FPGA), an application specific integrated circuit (ASIC), etc.), or other suitable processor.

The memory sub-system controller 106 can be a processing device, which includes one or more processors (e.g., processor 108), configured to execute instructions stored in a local memory 110. In the illustrated example, the local memory 110 of the memory sub-system controller 106 includes an embedded memory configured to store instructions for performing various processes, operations, logic flows, and routines that control operation of the memory sub-system 104, including handling communications between the memory sub-system 104 and the host system 102.

In some embodiments, the local memory 110 can include memory registers storing memory pointers, fetched data, etc. The local memory 110 can also include read-only memory (ROM) for storing micro-code. While the example memory sub-system 104 in FIG. 1 has been illustrated as including the memory sub-system controller 106, in another embodiment of the present disclosure, a memory sub-system 104 does not include a memory sub-system controller 106, and can instead rely upon external control (e.g., provided by an external host, or by a processor or controller separate from the memory sub-system).

In general, the memory sub-system controller 106 can receive commands or operations from the host system 102 and can convert the commands or operations into instructions or appropriate commands to achieve the desired access to the memory device 112 and/or the memory device 114. The memory sub-system controller 106 can be responsible for other operations such as wear leveling operations, garbage collection operations, error detection and ECC operations, encryption operations, caching operations, and address translations between a logical address (e.g., logical block address (LBA), namespace) and a physical address (e.g., physical block address) that are associated with the memory devices 112, 114. The memory sub-system controller 106 can further include host interface (not pictured) circuitry to communicate with the host system 102 via a physical host interface (not pictured). The host interface circuitry can convert the commands received from the host system into command instructions to access the memory device 112 and/or the memory device 114 as well as convert responses associated with the memory device 112 and/or the memory device 114 into information for the host system 102.

The memory sub-system 104 can also include additional circuitry or components that are not illustrated. In some embodiments, the memory sub-system 104 can include a cache or buffer (e.g., DRAM) and address circuitry (e.g., a row decoder and a column decoder) that can receive an address from the memory sub-system controller 106 and decode the address to access the memory device 112 and/or the memory device 114.

In some embodiments, the memory device 114 includes a local media controller 116 that can operate in conjunction with memory sub-system controller 106 to execute operations on one or more memory cells of the memory devices 114. An external controller (e.g., memory sub-system controller 106) can externally manage the memory device 114 (e.g., perform media management operations on the memory device 114). In some embodiments, a memory device 114 is a managed memory device, which is a raw memory device combined with a local controller (e.g., local controller 116) for media management within the same memory device package.

As shown in FIG. 1, the memory device 114 can include a memory array 118. Although a single memory array is shown in FIG. 1 for simplicity and so as not to obscure embodiments of the present disclosure, memory device 114 can include a number of memory arrays analogous to array 118. In some embodiments, the memory array (e.g., array of memory cells) 118 can include a plurality of vertical TFTs. In some embodiments, the vertical TFTs can be asymmetric vertical TFTs. As used herein, the term “asymmetric vertical TFT” can refer to a TFT that has two different bias conditions. The asymmetric vertical TFT can facilitate the functions of a memory cell regardless of whether a voltage applied to the sense line coupled to the asymmetric vertical TFT has a positive polarity or a negative polarity. For example, the asymmetric vertical TFT can have the same voltage across its gate regardless of the polarity of the voltage of the sense line coupled to the asymmetric vertical TFT. In some embodiments, the gate voltage can be −3.8 V when the voltage across the sense line is −3.8 V and the gate voltage can continue to be −3.8 V when the voltage across the sense line is 3.8 V.

FIG. 2 is an example of a portion of a 3D vertical memory array 201 in accordance with a number of embodiments of the present disclosure. FIG. 2 includes levels 205-(N−1), 205-(N), and 205-(N+1) (individually or collectively referred to as levels 205) of two-dimensional (2D) arrays of memory cells, access lines 207-(N−1), 207-(N), and 207-(N+1) (individually or collectively referred to as access lines 207), dielectric materials 228-(N−1), 228-(N), 228-(N+1), and 228 (N+2) (individually or collectively referred to as dielectric materials 228), storage materials 225-(N−1), 225-(N), and 225-(N+1) (individually or collectively referred to as storage materials 225), a sense line 229, and a substrate 203. The substrate 203 can extend in a first direction (D1) 211 and a second direction (D2) 213 and the levels 205 of the arrays of memory cells can be stacked on top of each other in a third direction (D3) 215.

In some embodiments, the 3D vertical memory array 201 can be a portion of a larger memory array (e.g., memory array 118 in FIG. 1). Each level 205 of the 3D vertical memory array 201 can include an associated access line (e.g., word line) 207 extending substantially parallel to the substrate 203 at a corresponding distance along the third direction (D3) 215 with respect to the substrate 203. The 3D vertical memory array 201 can further include sense lines 229 in the form of conductive pillars, only one being depicted in FIG. 2, extending substantially perpendicular to the substrate 203 along the third direction (D3) 215.

In some embodiments, the memory cells of each level 205 can be self-selecting memory cells comprising storage material 225, such as chalcogenide material. More specifically, the chalcogenide material can include a chalcogenide alloy and/or glass that may serve as a self-selecting data storage element material (i.e., a material that may serve as both a select device and a data storage element).

The architecture of the 3D vertical memory array 201 may be referred to as a cross-point architecture in which a memory cell is formed at a topological cross-point between an access line 207 and a sense line 229. A storage material 225 can be in contact with a corresponding access line 207 associated with a level 205 and a corresponding sense line 229. Such a cross-point architecture may offer relatively high-density data storage with lower production costs compared to other memory architectures. For example, the cross-point architecture may have memory cells with a reduced area and, resultantly, an increased memory cell density compared to other architectures.

According to this architecture, memory cells of each level 205 can be vertically stacked along the third direction (D3) 215 above the memory cells of the underlying level (e.g., level 205 (N−1)). A storage material (e.g., storage material 225-(N)) can be located above the storage material (e.g., storage material 225 (N−1)) of the underlying level and is electrically insulated from the latter by means of a dielectric (insulating) material 228-(N) located between the storage materials 225-(N−1) and 225-(N).

In some embodiments, the substrate 203 may comprise a plurality of contacts (not shown in FIG. 2) arranged in a grid or staggered pattern. For example, the plurality of contacts may extend through the substrate 203 and couple with sense lines 229. In some embodiments, a vertical thin film transistor (TFT) (e.g., TFT 355 in FIG. 3) can couple the sense line 229 to the substrate 203 via a contact extending through the substrate 203.

In some embodiments, a memory cell can be accessed through a selected access line 207 and a selected sense line 229 for receiving program and/or read pulses. The storage material 225 can be responsive to an applied voltage, such as a program pulse. For an applied voltage that is less than a threshold voltage, the storage material 225 may remain in an electrically nonconductive state corresponding, for example, to a “RESET” state (or logic “0”). Responsive to an applied voltage that is greater than the threshold voltage, the storage material 225 may enter an electrically conductive state corresponding, for example, to a “SET” state (or logic “1”). As used herein, the term “threshold voltage” refers to a value of a voltage that would cause the storage material 225 to change from a nonconductive state to a conductive state when applied to the storage material 225.

The storage material 225 may be programmed to a target logic state by applying a pulse (e.g., a program pulse) that satisfies a programming threshold. The amplitude, shape, or other characteristics of the program pulse may be configured to cause the storage material 225 to exhibit the target logic state. For example, after applying the program pulse, the ions of the storage material 225 may be redistributed throughout the storage material 225, thereby altering a resistance of the memory cell detected when a read pulse is applied. In some embodiments, the storage material 225 may be programmed to a target logic state by one or more pulses of a positive or a negative polarity applied to the selected access line 207 and the selected sense line 229.

In some embodiments, the logic state stored by the storage material 225 may be sensed, detected, or read by applying a read pulse to the storage material 225. The amplitude, shape, and/or other characteristics of the read pulse can be configured to allow a sense component to determine the logic state of the storage material 225. For example, in some embodiments, the amplitude of the read pulse can be configured to be at a level that the storage material 225 will conduct current for a first logic state such as the “SET” state (or logic “1”) but will conduct little to no current for a second logic state such as the “RESET” state (or logic “0”).

In some embodiments, the polarity of the pulse (whether program pulse or read pulse) applied to the storage material 225 may affect the outcome of the operation being performed on a corresponding memory cell. For example, a read pulse of a first polarity may result in the storage material 225 exhibiting a first logic state while a read pulse of a second polarity may result in the storage material 225 exhibiting a second, different logic state. This may occur because of the asymmetrical distributions of ions or other material in the storage material 225. Similar principles apply to program pulses and other pulses or voltages.

FIG. 3 is a schematic view of an asymmetric vertical thin film transistor (TFT) 355 selector in accordance with a number of embodiments of the present disclosure. As shown in FIG. 3, TFT 355 includes a first source/drain region 358-1, a second source/drain region 358-2, a channel 360 separating the first and second source/drain regions 358, and gates 362-1 and 362-2 separated from channel 360. Although not shown in FIG. 3 for clarity and so as not to obscure embodiments of the present disclosure, TFT 355 can be formed on a substrate, and gates 362 can be separated from channel 360 by a dielectric material, as will be further described herein (e.g. in connection with FIGS. 4A-4G). The first source/drain region 358-1 and the second source/drain region 358-2 can have different doping concentrations in different portions thereof, as illustrated in FIG. 3. For example, a portion of each source/drain region 358 that is nearer to (e.g., in direct contact with) the channel 360 can have a doping concentration that is less than the doping concentration of the channel 360 and greater than the doping concentrations of the portions of the source/drain regions 358 that are farther away from (e.g., not in direct contact with) the channel 360.

As shown in FIG. 3, a first end of channel 360 is coupled to (e.g., in direct contact with) first source/drain region 358-1 and extends beyond a first end of gates 362, and a second (e.g., opposite) end of channel 360 is coupled to (e.g., in direct contact with) second source/drain region 358-2 and does not extend beyond a second end of gates 362 opposite the first end of gates 362. For example, the first source/drain region 358-1 can be outside (e.g., completely outside) a gate region and the second source/drain region 358-2 (e.g., a portion of second source/drain region 358-2) can be within the gate region. As used herein, the term “gate region” refers to an area between the gates 362 that extends the length of each gate 362. Forming the vertical TFT 355 such that the first source/drain region 358-1 is outside of the gate region and the second source/drain region 358-2 is within of the gate region can reduce an electric field at the first end of the channel 360. The electric field at the first end of the channel 360 can be reduced because of the increased distance between a sense line coupled to the first end of the channel 360 and the gate 362.

In some embodiments, a sense line (e.g., sense line 229 previously described in connection with FIG. 2; not shown in FIG. 3 for clarity and so as not to obscure embodiments of the present disclosure) can be coupled to the first source/drain region 358-1. The sense line can be a first distance from the gates 362. Further, a storage node can be coupled to the second source/drain region 362-2. The storage node can be a second distance from the gates 362. The first distance from the gates 362 can be greater than the second distance from the gates 362. In some embodiments, the first distance can be 30 nanometers (nm).

The strength of an electric field between the first end of the channel 360 and the sense line can be determined based on a distance between the first end of the channel 360 and the first end of the gates 362. For example, the electric field at the first end of the channel 360 can increase as the distance between the first end of the channel 360 and the gates 362 decreases and the electric field at the first end of the channel 360 can decrease as the distance between the first end of the channel 360 and the gates 362 increases. Further, an amount of voltage leakage between the first end of the channel 360 and the sense line can be determined based on the distance between the first end of the channel 360 and the first end of the gates 362. For example, the amount of voltage leakage between the first end of the channel 360 and the sense line can increase as the distance between the first end of the channel 360 and the gates 362 decreases and the amount of voltage leakage between the first end of the channel 360 and the sense line can decrease as the distance between the first end of the channel 360 and the gates 362 increases. Therefore, the amount of leakage between the first end of the channel 360 and the sense line can be determined based on the strength of the electric field between the first end of the channel 360 and a sense line coupled to the first end of the channel 360.

In some embodiments, the vertical TFT 355 can be an access line selector and a pillar selector. As used herein, the term “access line selector” refers to a vertical TFT 355 that selects an access line coupled to the vertical TFT 355 when a voltage is applied to a source/drain region 358 of the vertical TFT. As used herein, the term “pillar selector” refers to a vertical TFT 355 that can select a component (e.g., sense line 229 in FIG. 2) coupled to the vertical TFT 355.

In some embodiments, an on current for the vertical TFT 355 can be much greater than an off current for the vertical TFT 355. For example, the on current for the vertical TFT 355 can be 100 microamps and the off current for the vertical TFT 355 can be less than 1 nanoamp. In some embodiments, the on current can have a value in a range of 10-100 microamps. As used herein, the term “on current” refers to a current that flows through the TFT when the memory cell is selected (e.g., being programmed) during a write operation. As used herein, the term “off current” refers to a current that flows through the TFT when the memory cell is not being selected during a write operation. The asymmetric property of the vertical TFT 355 allows a single vertical TFT 355 to sustain two different bias conditions. As used herein, the term “bias condition” refers to the current and voltage that allows a memory component to function (e.g., being programmed and sensed) as intended. Therefore, the asymmetric property of the vertical TFT 355 allows the vertical TFT 355 to sustain a first voltage and current requirement that allows the vertical TFT 355 to function as an access line selector and a second voltage and current requirement that allows the vertical TFT 355 to function as a pillar selector.

FIG. 4A is a cross-sectional view, at one stage of a semiconductor fabrication process, for forming asymmetric vertical TFTs (e.g., TFT 355 previously described in connection with FIG. 3) in accordance with a number of embodiments of the present disclosure. FIG. 4A includes a first dielectric material 472 formed on a substrate material 470. FIG. 4A also includes a semiconductor material 474 formed on the dielectric material 472. In some embodiments, the substrate material 470 can be a silicon material, the dielectric material 472 can be an oxide material, and the semiconductor material 474 can be a polysilicon material. As shown in FIG. 4A (e.g., as represented by the various shadings illustrated in FIG. 4A), the semiconductor material 474 can be doped in a manner similar to the vertical TFT 355 shown in FIG. 3.

FIG. 4B is a cross-sectional view, at another stage of a semiconductor fabrication process, for forming asymmetric vertical TFTs in accordance with a number of embodiments of the present disclosure. For instance, FIG. 4B shows the semiconductor material 474 after the semiconductor material 474 has been patterned. The patterning can be performed such that the patterning is visible when looking at the semiconductor material 474 from a perspective that is parallel to the gate (e.g., gate 362 in FIG. 3) cross-section. In some embodiments, the patterning can include forming a plurality of vertical openings through the semiconductor material 474 and forming the dielectric material 472, or another insulating material with a different composition than the dielectric material 472, in the vertical openings (e.g., filling the vertical openings with the dielectric material 472).

FIG. 4C is a cross-sectional view, at another stage of a semiconductor fabrication process, for forming asymmetric vertical TFTs in accordance with a number of embodiments of the present disclosure. For instance, FIG. 4C illustrates the semiconductor material 474 after it has been patterned subsequent to the patterning described in connection with FIG. 4B. The patterning shown in FIG. 4C can be performed such that the patterning is visible when looking at the semiconductor material 474 from a perspective that is perpendicular to a gate cross-section. The patterning in FIG. 4C can include forming a plurality of vertical openings 476 through the semiconductor material 474 to form vertical TFTs 455 having vertical sidewalls adjacent the plurality of vertical openings 476.

In some embodiments, each of the vertical TFTs 455 can have a width in a range of 10 nanometers to 100 nanometers. Each of the vertical TFTs 455 can include a first source/drain region (e.g., first source/drain region 358-1 in FIG. 3), a second source/drain region (e.g., second source/drain region 358-2 in FIG. 3), and a channel (e.g., channel 360 in FIG. 3) separating the first source/drain region and second source/drain region.

FIG. 4D is a cross-sectional view, at another stage of a semiconductor fabrication process, for forming asymmetric vertical TFTs in accordance with a number of embodiments of the present disclosure. For instance, FIG. 4D illustrates the plurality of vertical TFTs 455 after a second dielectric material 478 is formed (e.g., deposited) over (e.g., on) the vertical TFTs 455 and in the vertical openings 476 (e.g., at the bottom of vertical openings 476) and recessed from the vertical TFTs 455. In some embodiments, the second dielectric material 478 can be a sacrificial dielectric material. Further, in some embodiments, the second dielectric material 478 can be formed to a height in openings 476 in a range of 7 nanometers to 10 nanometers.

FIG. 4E is a cross-sectional view, at another stage of a semiconductor fabrication process, for forming asymmetric vertical TFTs in accordance with a number of embodiments of the present disclosure. For instance, FIG. 4E illustrates the plurality of vertical TFTs 455 after a gate dielectric material 479 is formed over (e.g., on) the vertical TFTs 455 and the dielectric material 478. In some embodiments, the gate dielectric material 479 can be an oxide material.

FIG. 4F is a cross-sectional view, at another stage of a semiconductor fabrication process, for forming asymmetric vertical TFTs in accordance with a number of embodiments of the present disclosure. For instance, FIG. 4F illustrates the plurality of vertical TFTs 455 after a gate electrode material 480 is formed over the gate dielectric material 479.

FIG. 4G is a cross-sectional view, at another stage of a semiconductor fabrication process, for forming asymmetric vertical TFTs in accordance with a number of embodiments of the present disclosure. For instance, FIG. 4G illustrates the plurality of vertical TFTs 455 after the gate dielectric material 479 and the gate electrode material 480 have been recessed from the vertical TFTs 455 to form gates 462. In some embodiments, each of the gates 462 can be formed to a length in a range of 50 to 150 nanometers. The height of the gates 462 can be determined by the height of the second dielectric material 478 deposited in the vertical openings 476 and the distance the gate electrode material 480 was recessed from the top of a vertical TFT 455. As previously described, a first end of the channel can be coupled to the first source/drain region and extend beyond a first end of the gate 462 and a second end of the channel can be coupled to the second source/drain region and may not extend beyond a second end of the gate 462 that is opposite the first end of the gate 462. Further, the gates 462 can be separated from the TFT 455 by the gate dielectric material 479.

The plurality of vertical TFTs can be included in an array of memory cells (e.g., memory array 118 in FIG. 1). In some embodiments, at least one of the plurality of vertical TFTs 455 can have a gate-source voltage of −3.8 volts (V) and a drain-source voltage of 3.8 V. Alternatively, at least one of the plurality of vertical TFTs 455 can have a gate-source voltage of 0 V and a drain-source voltage of 3.8 V. As used herein, the term “gate-source voltage” refers to the voltage across the gate-source terminal of a TFT during a program operation on the memory cell. As used herein, the term “drain-source voltage” refers to the voltage across the drain-source terminal of a TFT during a program operation on the memory cell. TFTs 455 can have these combinations of gate-source voltages and drain-source voltages because each of the TFT's 455 width is in a range of 10 nanometers to 100 nanometers.

As used herein, “a,” “a number of” or a “quantity of” something can refer to one or more of such things. For example, a number of or a quantity of memory cells can refer to one or more memory cells. A “plurality” of something can refer to two or more of such things.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” an other element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. An apparatus, comprising:
a first source/drain region and a second source/drain region formed on a substrate;
a channel separating the first source/drain region and the second source/drain region;
a gate separated from the channel by a gate dielectric material, wherein:
the first source/drain region, the second source/drain region, the channel and the gate form a vertical thin film transistor (TFT);
a first end of the channel is coupled to the first source/drain region and extends beyond a first end of the gate; and
a second end of the channel is coupled to the second source/drain region and does not extend beyond a second end of the gate that is opposite the first end of the gate;
a contact in the substrate coupled to the first source/drain region; and
a sense line coupled to the second source/drain region.

2. The apparatus of claim 1, wherein the first source/drain region is outside a gate region and the second source/drain region is within the gate region.

3. The apparatus of claim 1, wherein the vertical TFT sustains a first bias condition corresponding to a first function of the vertical TFT and sustains a second bias condition corresponding to a second function of the vertical TFT.

4. The apparatus of claim 3, wherein the first bias condition includes a first voltage requirement and a first current requirement and the second bias condition includes a second voltage requirement and a second current requirement.

5. The apparatus of claim 3, wherein the first function is an access line selector and the second function is a pillar selector.

6. The apparatus of claim 5, wherein an on current for the vertical TFT is in a range of 10-100 microamps.

7. The apparatus of claim 5, wherein an off current for the vertical TFT is less than 1 nanoamp.

8. A memory device, comprising:
an array of memory cells, wherein the array of memory cells includes a plurality of vertical thin film transistors (TFTs), wherein each of the vertical TFTs includes:
a semiconductor material, wherein the semiconductor material includes a first source/drain region, a second source/drain region, and a channel separating the first source/drain region and the second source/drain region; and
a gate separated from the channel by a gate dielectric material, wherein:
a first end of the channel is coupled to the first source/drain region and extends beyond a first end of the gate; and
a second end of the channel is coupled to the second source/drain region and does not extend beyond a second end of the gate that is opposite the first end of the gate.

9. The memory device of claim 8, wherein the gate dielectric material is an oxide material.

10. The memory device of claim 8, wherein the semiconductor material is a polysilicon material.

11. The memory device of claim 8, wherein at least one of the plurality of vertical TFTs has a gate-source voltage of −3.8 volts (V) and a drain-source voltage of 3.8 V.

12. The memory device of claim 8, wherein at least one of the plurality of vertical TFTs has a gate-source voltage of 0 volts (V) and a drain-source voltage of 3.8 V.

13. The memory device of claim 8, wherein the array memory cells is a three-dimensional vertical array of memory cells.

14. The memory device of claim 8, wherein each memory cell in the array of memory cells includes a horizontal access line, a storage material coupled to the horizontal access line, and a dielectric material coupled to the storage material in a horizontal direction.

15. A method, comprising:
forming a dielectric material on a substrate material;
forming a semiconductor material on the dielectric material;
forming a plurality of vertical openings through the semiconductor material to form vertical thin film transistors (TFTs) having vertical sidewalls adjacent the plurality of vertical openings, wherein each of the vertical TFTs includes a first source/drain region, a second source/drain region, and a channel separating the first source/drain region and the second source/drain region;
forming a gate dielectric material in the vertical openings;
forming a gate electrode material over the vertical TFTs and the gate dielectric material, wherein the gate dielectric material separates the gate electrode material and the channel; and
recessing the gate electrode material from the vertical TFTs to form a gate, wherein:
a first end of the channel is coupled to the first source/drain region and extends beyond a first end of the gate; and
a second end of the channel is coupled to the second source/drain region and does not extend beyond a second end of the gate that is opposite the first end of the gate.

16. The method of claim 15, further comprising forming the gate to a length in a range of 50 to 150 nanometers.

17. The method of claim 15, further comprising forming the dielectric material to a height in a range of 7 nanometers (nm) to 10 nm.

18. The method of claim 15, further comprising forming the vertical TFT to a width of 100 nanometers.

19. The method of claim 15, further comprising determining a strength of an electric field between the first end of the channel and a sense line coupled to the first source/drain region based on a distance between the first end of the channel and the first end of the gate.

20. The method of claim 15, further comprising determining an amount of voltage leakage between the first end of the channel and a sense line coupled to the first end of the channel based on a distance between the first end of the channel and the first end of the gate.
